(19) United States
(12) Patent Application Publication
(10) Pub. No.: US 2012/0267658 A1
(43) Pub. Date: Oct. 25, 2012

(54) LARGE-AREA LIGHT-EMITTING DEVICE AND METHOD FOR FABRICATING THE SAME

(75) Inventors: Jianping Zhang, El Monte, CA (US); Chunhui Yan, El Monte, CA (US)

(73) Assignee: INVENLUX LIMITED, CENTRAL (HK)

(21) Appl. No.: 13/090,918

(22) Filed: Apr. 20, 2011

(51) Int. Cl. H01L 33/46; H01L 33/02

(52) U.S. Cl. 257/98; 257/103; 438/29; 257/E33.06; 257/E33.023

(57) ABSTRACT

A III-nitride light emitting device having a substrate with a conductive grid made of conductive lines formed thereon. An active-region is sandwiched between an n-type layer and a p-type layer forming an LED structure, and the conductive grid is in ohmic contact with the n-type layer. Also provided is a method for fabricating the same.

### 1. FIELD OF THE INVENTION

The present invention relates in general to light-emitting devices, more particularly to large-area III-nitride light-emitting devices with improved uniformity of current injection.

### 2. DESCRIPTION OF THE RELATED ART

III-nitride based light-emitting devices such as light-emitting diodes (LEDs) are widely acknowledged as the next generation light sources and are currently emerging as strong replacement of incandescent and fluorescent lamps in general lighting. For example, the field of interest uses Cerium-doped yttrium aluminum garnet (YAG:Ce) phosphor to convert InGaN multiple-quantum-well (MQW) LED's blue emission into white light, yielding commercial white light LEDs with luminous efficacies in the range of 80-110 lm/W. The R&D luminous efficacy record reported so far by Nichia has reached 183 μm/W (Y. Narukawa et al, J. Phys. D: Appl. Phys. 43, 354002 (2010).).

LEDs projected for use in general lighting are preferred to be able to sustain high-current and high-current-density operations. General lighting oriented LEDs usually have large footprint, with the state-of-the-art dimensions measured to be close to or larger than 1×1 mm². For this purpose, uniform distribution of current injection through the whole device area is crucial.

In the prior art, such as that disclosed in U.S. Pat. No. 6,078,064, transparent conductive layer like indium tin oxide (ITO) is widely used for p-type current spreading. For further better current spreading, grooves are made through p-type layers and active-region into n-type layers, for the formation of n-contact fingers to access n-type current spreading layer. As a result, any resultant n-contact finger is spaced by a p-contact finger away from another n-contact finger, and vice versa. This is illustrated in FIG. 1, wherein the plane-view schematic drawing of a prior art large area LED is presented. More drawings of prior art large area LEDs can be found in U.S. Pat. No. 6,885,036. As shown, p-electrode 810 (comprising p-contact fingers 812 and p-pad 811) and n-electrode 820 (comprising n-contact fingers 822 and n-pad 821) are positioned in the opposite side of the LED chip, with four p-current spreading fingers 812 spaced by three n-current spreading fingers 822. P-electrode 810 and n-electrode 820 are formed on ITO 60 and within groove 823, respectively. Groove 823 can be formed by removal of layers of p-type material, active-region, and n-type material until exposing n-type current spreading layer n-GaN 23′. N-electrode 820 is formed within groove 823 directly on n-current spreading layer 23′. By proper design of the n- and p-electrode fingers in the prior art, a uniform current flow is enabled between n- and p-electrodes, however at the expense of portions of light-emitting active-region.

### 3. SUMMARY OF THE INVENTION

The present invention is directed to a light emitting device with improved uniformity of current injection without overly sacrificing active-region, a wafer substrate having conductive grid for a light emitting device, and a method for fabricating the same.

Highly conductive grid is formed on a substrate or template for a light-emitting device, then LED structure is formed on the conductive grid on the substrate.

One aspect of the invention provides a III-nitride light emitting device, comprising

a substrate;

a conductive grid made of conductive lines formed on the substrate, wherein the conductive grid has a separation distance between the conductive lines in the range of 10-150 μm, a thickness of the conductive lines in the range of 0.5-2 μm, and a width of the conductive lines in the range of 5-15 μm;

an n-type layer formed on the substrate and the conductive grid, wherein the n-type layer is in ohmic contact with the conductive grid, either directly, or through conductive template or substrate on which the conductive grid overlying;

a p-type layer; and

an active-region sandwiched between the n-type layer and the p-type layer.

Another aspect of the invention provides a wafer substrate for III-nitride light emitting device, comprising

a substrate; and

a conductive grid made of conductive lines formed on the substrate, wherein the conductive grid has a separation distance between the conductive lines in the range of 10-150 μm, a thickness of the conductive lines in the range of 0.5-2 μm, and a width of the conductive lines in the range of 5-15 μm.

Another aspect of the invention provides a wafer for III-nitride light emitting device comprising:

a wafer substrate comprising a substrate, and a conductive grid made of conductive lines formed on the substrate, wherein the conductive grid has a separation distance between the conductive lines in the range of 10-150 μm, a thickness of the conductive lines in the range of 0.5-2 μm, and a width of the conductive lines in the range of 5-15 μm;

an n-type layer formed on the wafer substrate;

an active-region formed on the n-type layer; and

a p-type layer formed on the active-region.

Another aspect of the invention provides a method for fabricating III-nitride light emitting device, comprising

providing a substrate or a template comprising an template layer epitaxially formed on the substrate;

forming a conductive grid made of conductive lines on the substrate or the template, wherein the conductive grid has a separation distance between the conductive lines in the range of 10-150 μm, a thickness of the conductive lines in the range of 0.5-2 μm, and a width of the conductive lines in the range of 5-15 μm;

forming an n-type layer on the substrate or the template and the conductive grid, wherein the n-type layer is in ohmic contact with the conductive grid, either directly, or through the conductive template layer or substrate on which the conductive grid overlying;

forming an active-region on the n-type layer; and

forming a p-type layer on the active-region.

### 4. BRIEF DESCRIPTION OF THE DRAWINGS

The accompanying drawings, which are included to provide a further understanding of the invention and constitute a part of this application, illustrate embodiments of the invention and together with the description serve to explain the principle of the invention. Like reference numbers in the figures refer to like elements throughout, and a layer can refer to a group of layers associated with the same function.

FIG. 1 illustrates the plane-view drawing of a prior-art large-area light-emitting diode.

FIG. 2A illustrates the plane view of a conductive grid formed on a template or substrate according to one aspect of the present invention.

FIG. 2B illustrates the cross-sectional view of a conductive grid formed on a template or substrate according to one aspect of the present invention.

FIG. 2C illustrates the cross-sectional view of a conductive grid formed on a template or substrate according to one aspect of the present invention.

FIG. 2D illustrates the cross-sectional view of a conductive grid formed on a template or substrate according to one aspect of the present invention.

FIG. 3A and FIG. 3B illustrate large-area LED embodiments formed over conductive grid shown in FIGS. 2A-2D according to the present invention.

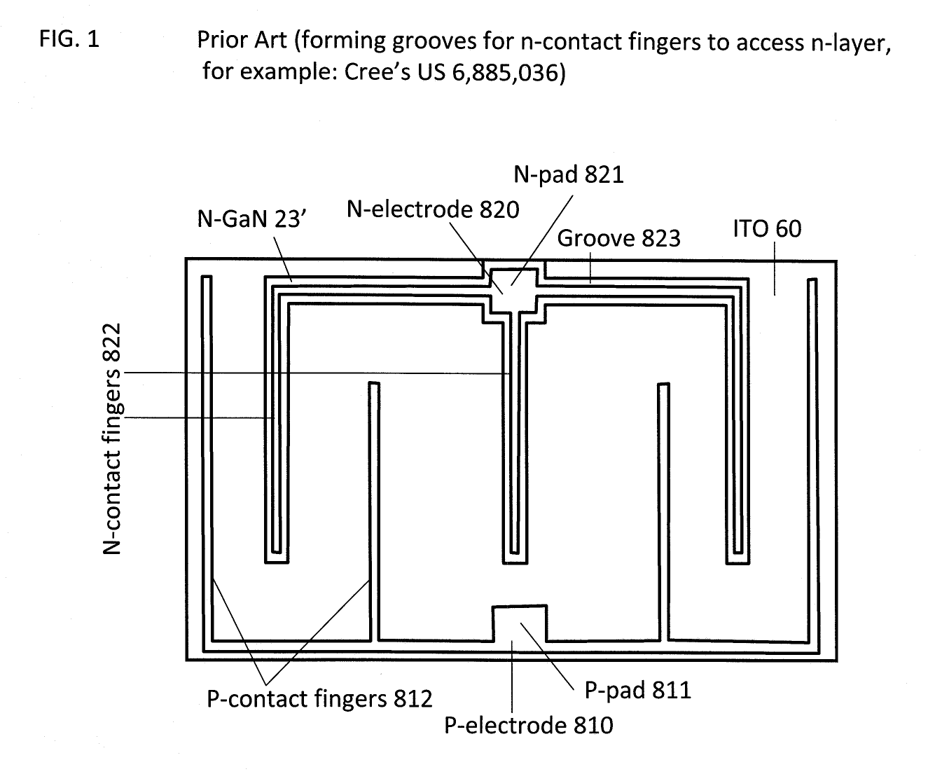

### 5. DETAILED DESCRIPTION OF EMBODIMENTS

Materials used to form the conductive grid are preferred to have resistivity less than 50 μΩ·cm, and are inert to chemical ambient containing hydrogen, nitrogen, and ammonia at elevated temperatures greater than 800° C. It is also desirable that the conductive grid can have a light reflectivity greater than 50% for visible light. It is further preferable that group-III nitrides can be epitaxially deposited on the conductive grid, and can form an ohmic contact to the conductive grid. Two materials contact to each other forming ohmic contact means a linear current-voltage relationship can be realized when biasing a voltage across the interface formed by the two materials.

Materials of interest to form the conductive grid include groups IIIB-VIB nitrides, i.e., including Scandium nitride (ScN), Yttrium nitride (YN), Titanium nitride (TiN), Zirconium nitride (ZrN), Hafnium nitride (HfN), Vanadium nitride (VN), Niobium nitride (NbN), Tantalum nitride (TaN), Chromium nitride (CrN), Molybdenum nitride (MoN), and Tungsten nitride (WN). It is not necessary, but desirable, that these transition metal nitrides to be stoichiometric.

The conductive grid can be a two-dimensional grid such as a square grid, a hexagonal grid, a polar grid or modified polar grid, or a grid with other patterns. The conductive grid can also be a one-dimensional grid such as parallel lines, parallel zigzag lines. The conductive grid can be uniformly distributed over the wafer, or have higher density in certain areas than other areas on the wafer.

The conductive grid can be made of conductive lines on the surface of a substrate or a template, or formed in trenches in a substrate or a template layer. The thickness b of the conductive lines can be in the range of 0.5-2 μm, such as 1-1.5 μm, the width c of the conductive lines can be in the range of 5-15 μm, such as 8-10 μm. A periodic separation distance a between the conductive lines can be in the range of 10-150 μm, such as 50-100 μm.

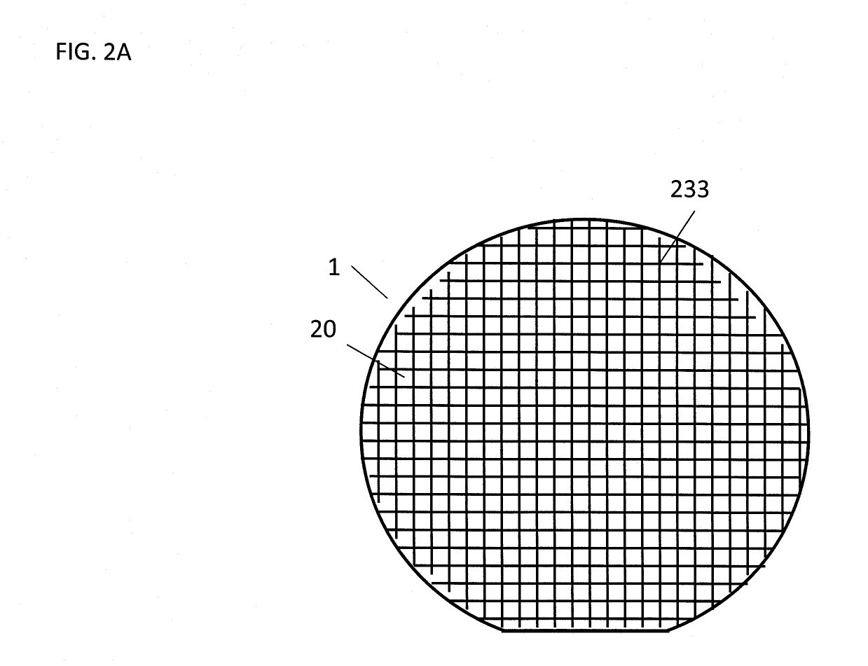

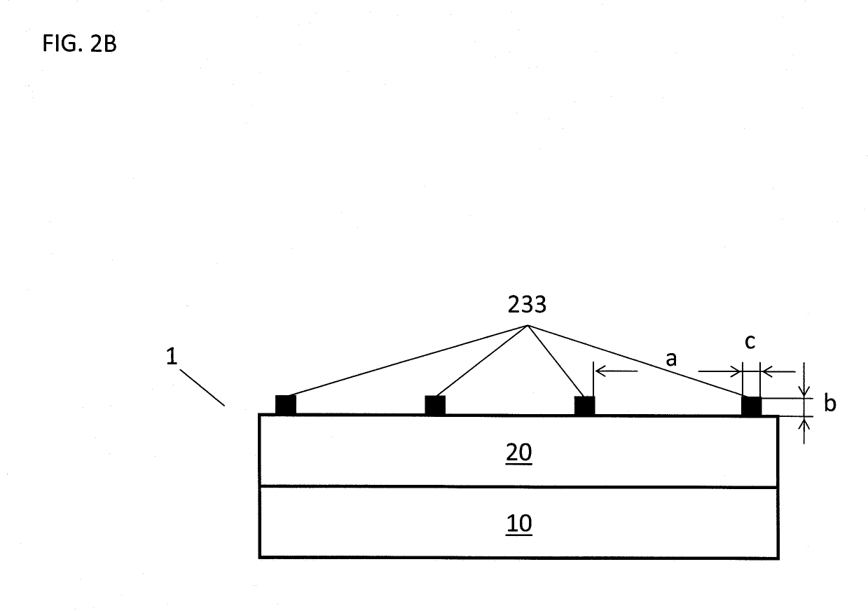

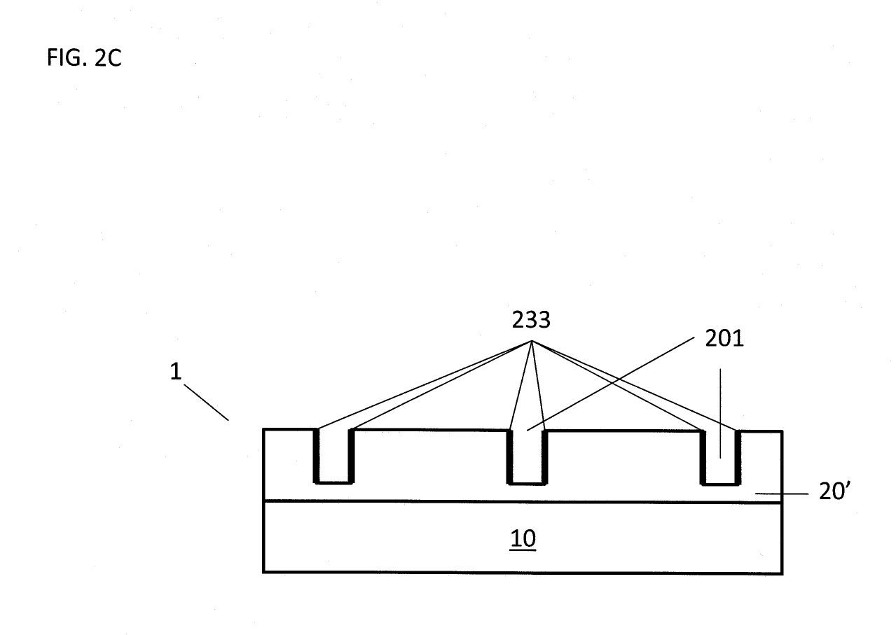

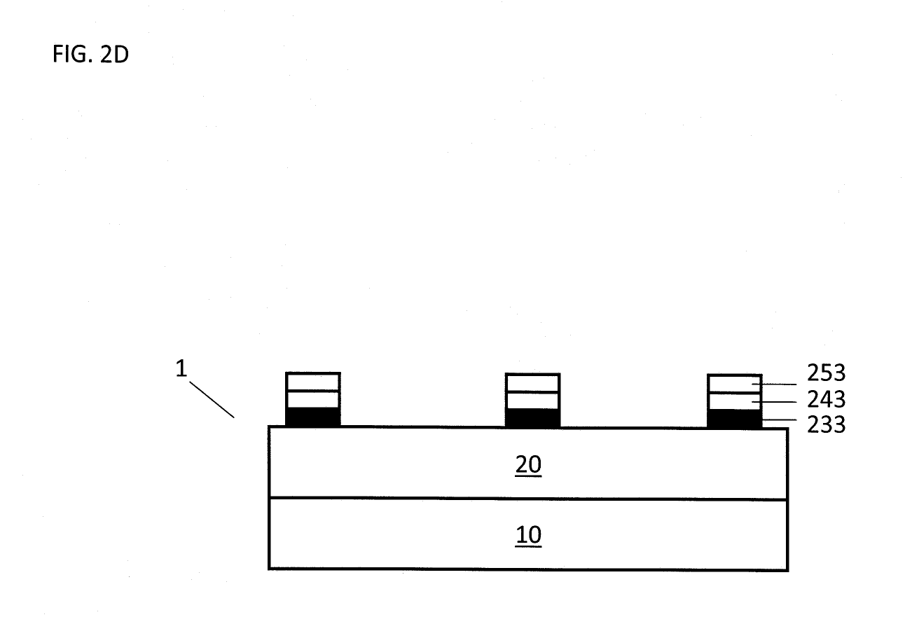

FIG. 2A illustrates the plane view (in wafer scale) of a conductive grid 233 made of conductive lines formed on a template 1 or substrate 10 according to one aspect of the present invention. Substrate 10 of interest can be sapphire, silicon, silicon carbide, gallium nitride, aluminum nitride, gallium arsenide, spinel and the like. Template 1 consists of substrate 10 and an epitaxially formed template layer 20, which can be group-III nitride AlₓIn_{y}Ga_{1-x-y}N (0<=x<=1; 0<=y<=1). For group-III nitride visible LEDs, template layer 20 is preferably to be AlₓIn_{y}Ga_{1-x-y}N with 0=<x+y<=0.1. Template layer 20 is preferred to be of n-type conductivity with electron concentration greater than 5×10¹⁸ cm⁻³, formed, for example, with Si-doping, so that template layer 20 forms ohmic contact with conductive grid 233.

N-type layer, active-region, p-type layer and ITO layer are formed on template 1 or substrate 10 in sequence by known methods. The n-type layer can directly contact with conductive grid 233. The n-type layer can be Si-doped GaN, or InGaN, or AlGaN, with average In or Al composition less than 10%, for example 3%-7%, for visible LEDs, respectively. To ensure ohmic contact between conductive grid 233 and the n-type layer, the bottom portion of the n-type layer can be heavily doped with silicon. That is to say, the first 0.1-0.5 μm of the n-type layer can be Si-doped with silicon concentration in the range of 5-50×10¹⁸ cm⁻³, the doping level is reduced to normal such as 5×10¹⁸ cm⁻³ or less in upper portion of the n-type layer. The active-region can be made of GaN/InGaN multiple-quantum-well, and the p-type layer can be Mg-doped p-GaN, p-AlGaN, and p-InGaN. The ITO layer, usually of thickness of 200-400 nm, is used to spreading current for p-layer. Further processing of the wafer with known method, a plurality of LED structures can be formed on the wafer.

FIGS. 2B and 2C illustrate two preferred cross-sectional views of FIG. 2A. In FIG. 2B, conductive grid 233 is formed on template layer 20, preferably with a periodic separation distance a between the conductive lines in the range of 50-150 μm such as 80-110 μm (separation distance a is defined as the perpendicular distance between two neighboring parallel conductive lines), and with a thickness b of the conductive line in the range of 0.5-2 μm such as 1-1.5 μm, a width c of the conductive line in the range of 5-10 μm such as 6-8 μm. Though as shown in FIG. 2A, conductive grid 233 is a two-dimensional square grid, it can be other two-dimensional grids as well, such as a hexagonal grid, a polar grid, or a grid with other patterns. In this embodiment, the conductive grid is uniformly distributed over the wafer. The conductive grid can also be unevenly distributed over the wafer.

The conductive grid 233 shown in FIG. 2A and FIG. 2B can be formed via known methods in the prior art such as lithography and deposition. Conductive grid 233, made of groups IIIB-VIB nitrides, can be formed on template layer 20 via known methods such as magnetron sputtering, electron-beam deposition, atomic layer deposition, metalorganic chemical vapor deposition (MOCVD), or physical vapor deposition. The vapor formation of such transition metal nitrides can be found in the prior art, for example, in the paper on Growth and physical properties of epitaxial HfN layers on MgO (001), by H.-S. Seo, et al in Journal of Applied Physics, Vol 96, pp 878-884 (2004), or in another paper on Organometallic vapor phase epitaxial growth of GaN on ZrN/AlN/Si substrate, by M. H. Oliver, et al in Applied Physics Letters, Vol 93, 023109 (2008). The conductive grid 233 can also be formed directly on substrate 10 without using template layer 20.

In FIG. 2C, to minimize light absorption, conductive grid 233 is formed on the vertical walls of trenches 201 formed in template layer 20′. Trenches 201 are formed via standard lithographic and etching process known in the art. The trenches are of depth of 3-5 μm, width of 2-15 μm, and separation distance between the trenches in the range of 20-150 μm. Conductive grid 233 with thickness of 0.5-2 μm is then deposited on the vertical walls of trenches 201 via sputtering deposition. The trenches 201 can also be formed in substrate 10 without using the template layer.

Another embodiment of conductive grid 233 is shown in FIG. 2D, wherein additional layers 243 and 253 are conformably formed on conductive grid 233. Layers 243 and 253 can be made of silicon dioxide (SiO₂), silicon nitride (SiNₓ), or titanium oxide (TiO₂), respectively. Layers 243 and 253 can be a single protection layer made of SiO₂, SiN_{X}, or TiO₂ with a thickness great than 100 nm, providing protection to conductive grid 233 during the succeeding MOCVD growth of n-type layer 23 from hot hydrogen attack.

The conductive grid structure shown in FIG. 2D can be formed via known methods in the prior art such as lithography and deposition. First a metallic conductive layer is deposited on template layer 20, then layer 243 and layer 253 are sequentially deposited on the metallic conductive layer. The metallic conductive layer can also be deposited directly on substrate 10 without using template layer 20. Layer 253, layer 243 and the metallic conductive layer are etched to form the conductive grid 233 from the metallic conductive layer, and the conductive grid is covered with conformable layer 253 and layer 243 resulting from etching process. Layers 243 and 253 can be deposited via known methods such as chemical vapor deposition, magnetron sputtering, atomic layer deposition, or physical vapor deposition. Similarly, conductive grid 233, layer 243 and layer 253 can be sequentially deposited into trenches 201 as shown in FIG. 2C.

Layers 243 and 253 can be different layers in other embodiment. For example, layer 243 can be SiO₂ layer and layer 253 can be TiO₂ layer. Layer 243 and layer 253 are preferred to be formed on conductive grid 233 alternately a plurality of times. That is to say, layer 243 and layer 253 form a distributed Bragg reflector (DBR). The requirements of forming a good DBR is known in the art. In this embodiment, if layer 243 is SiO₂ and layer 253 is TiO₂, layer pair 243/253 can be formed alternately for 5-20 times. The thicknesses of each layer 243 and each layer 253 can be in the range of 50-100 nm such as 30-70 nm, respectively. Since layer pairs 243/253 forming DBR in this embodiment, light coming from above conductive grid 233 will be reflected back, with reflectivity greater than 95%, even greater than 99%. In this DBR plus conductive grid embodiment, because of the reduced light absorption by conductive grid 233, distance a between the conductive lines of conductive grid 233 can be reduced to the range of 10-50 μm, and width c of the conductive line can be increase to the range of 5-15 μm for improved current spreading effect without sacrificing light extraction efficiency. This DBR plus conductive grid embodiment presents a conductive reflector template for the following LED structure growth with improved device performance in terms of electrical and optical characteristics.

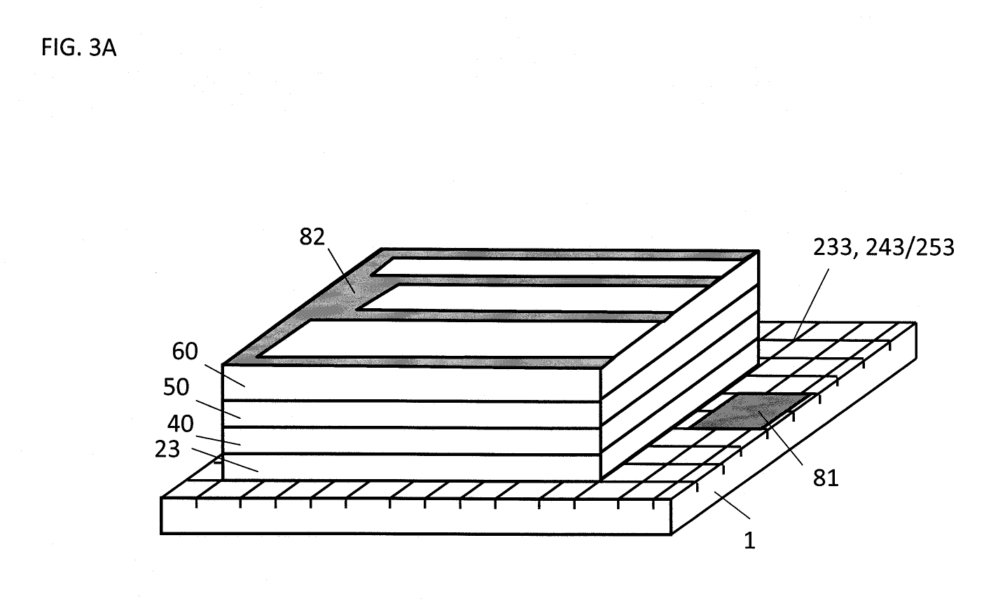

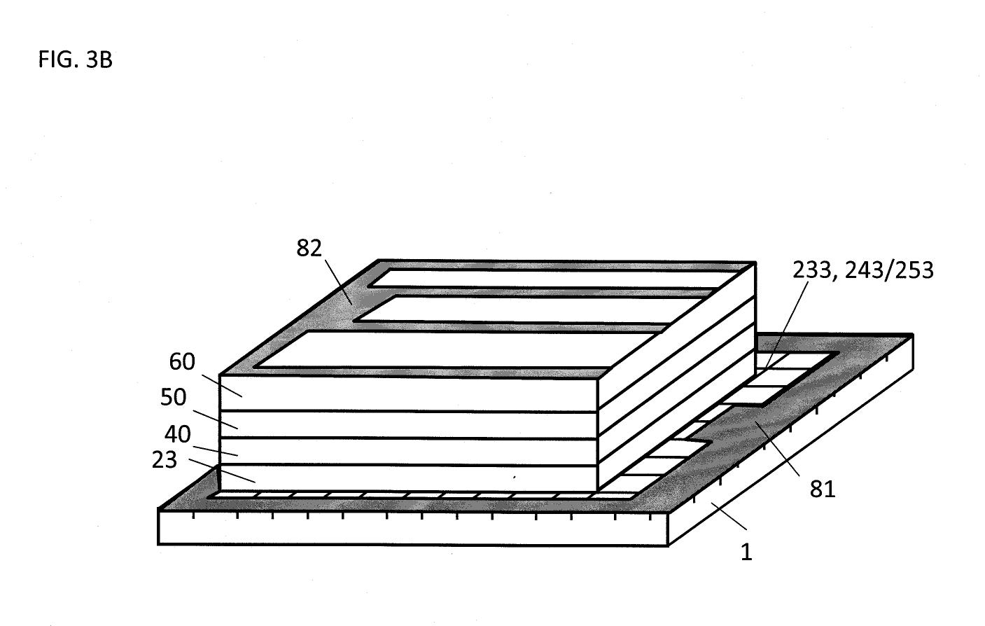

Shown in FIG. 3A is the perspective view of an LED chip according to an embodiment of the present invention. The chip can have a pn junction area larger than 200 mil², for example, of 400-10,000 mil². The LED structure is formed on template 1 as shown in FIGS. 2A-2D or formed directly on substrate 10. Substrate 10 can be a patterned sapphire substrate. Formed over substrate 10 is an undoped or silicon-doped GaN template layer 20. The LED structure formed above template 1 can be any known LED structure used in the art. For example, the LED structure can be III-nitride LED structure comprising n-type layer 23, active-region 40, p-type layer 50 and ITO layer 60 formed in sequence by known methods. A plurality of the LED structures are formed on a wafer by patterning and etching n-type layer 23, active-region 40, p-type layer 50 and ITO layer 60. Here each single LED structure is also referred to as an LED mesa. N-type layer 23 is formed on template 1 and can directly contact with conductive grid 233 and template layer 20 (FIG. 2B, FIG. 2C), or n-layer 23 is formed on template 1 and contacts template layer 20 and DBR layer pairs 243/253. N-type layer 23 can be Si-doped GaN, or InGaN, or AlGaN, with average In or Al composition less than 10%, for example 3%-7%, for visible LEDs, respectively. To ensure ohmic contact between conductive grid 233 and n-type layer 23, the bottom portion of n-type layer 23 can be heavily doped with silicon. That is to say, the first 0.1-0.5 μm of n-type layer 23 can be Si-doped with silicon concentration in the range of 5-50×10¹⁸ cm⁻³, the doping level is reduced to normal such as 5×10¹⁸ cm⁻³ or less in upper portion of n-type layer 23. Active-region 40 can be made of GaN/InGaN multiple-quantum-well, and p-type layers 50 can be Mg-doped p-GaN, p-AlGaN, and p-InGaN. ITO layer 60, usually of thickness of 200-400 nm, is used to spreading current for p-layers. Metal p-electrode 82 is formed on ITO 60 with current spreading fingers and a contact pad.

Conductive grid 233 made of groups IIIB-VIB nitrides can be highly conductive with electrical resistivity in the range of 10-50 μΩ·cm, providing superior lateral conduction for electron transport. Conductive grid 233 enables large area devices with improved uniformity current injection. As seen in FIG. 3A, metal n-electrode 81 virtually can be made only consisting of a contact pad, which sits on conductive grid 233, taking advantage of the superior electrical conductance of conductive grid 233 to uniformly spread current to n-type layer 23. Conductive grid 233 has very small resistance which makes the LED shown in FIG. 3A virtually a vertical conduction LED. To ensure even better injection uniformity, n-electrode 81 can be extended to contain a contact finger surrounding the LED mesa, as illustrated in FIG. 3B. In other embodiment, n-electrode 81 can be made to fully cover the whole area of the upper surface of template 1 that is exposed by n-type layer 23.

It will be apparent to those skilled in the art that various modifications and variations can be made to the disclosed embodiments without departing from the scope or spirit of the invention. In view of the foregoing, it is intended that the invention cover modifications and variations of this invention provided they fall within the scope of the following claims and their equivalents.

What is claimed is:

1. A III-nitride light emitting device, comprising
a substrate;
a conductive grid made of conductive lines formed on the substrate, wherein the conductive grid has a separation distance between the conductive lines in the range of 10-150 μm, a thickness of the conductive lines in the range of 0.5-2 μm, and a width of the conductive lines in the range of 5-15 μm;
an n-type layer formed on the substrate and the conductive grid, wherein the n-type layer is in ohmic contact with the conductive grid;
a p-type layer; and
an active-region sandwiched between the n-type layer and the p-type layer.

2. The III-nitride light emitting device of claim 1, further comprising an n-electrode in direct contact with the conductive grid, wherein the n-electrode comprises a contact pad and a finger surrounding an LED mesa.

3. The III-nitride light emitting device of claim 1, wherein a bottom portion of the n-type layer is more heavily doped with silicon than an upper portion of the n-type layer.

4. The III-nitride light emitting device of claim 1, further comprising an n-type template layer formed on the substrate, wherein the conductive layer is formed on and with ohmic contact to the template layer, the n-type layer is formed on the template layer and the conductive grid.

5. The III-nitride light emitting device of claim 1, further comprising a protection layer conformably formed on the conductive grid, wherein the protection layer is made of silicon dioxide, silicon nitride, or titanium dioxide.

6. The III-nitride light emitting device of claim 5, wherein the protection layer comprises one or more pairs of silicon dioxide/titanium dioxide layers forming a distributed Bragg reflector with visible light reflectivity greater than 95%.

7. The III-nitride light emitting device of claim 4, wherein the conductive grid is formed as conductive lines on the template layer, or as conductive lines in trenches in the template layer.

8. The III-nitride light emitting device of claim 1, wherein the conductive grid is formed as conductive lines on the substrate, or as conductive lines in trenches in the substrate.

9. The III-nitride light emitting device of claim 1, wherein the conductive grid is a two-dimensional square grid, or a hexagonal grid, and is uniformly distributed over the substrate.

10. The III-nitride light emitting device of claim 1, wherein the conductive grid is made of Scandium nitride (ScN), Yttrium nitride (YN), Titanium nitride (TiN), Zirconium nitride (ZrN), Hafnium nitride (HfN), Vanadium nitride (VN), Niobium nitride (NbN), Tantalum nitride (TaN), Chromium nitride (CrN), Molybdenum nitride (MoN), or Tungsten nitride (WN).

11. A wafer substrate for III-nitride light emitting device, comprising
a substrate; and
a conductive grid made of conductive lines formed on the substrate, wherein the conductive grid has a separation distance between the conductive lines in the range of 10-150 μm, a thickness of the conductive lines in the range of 0.5-2 μm, and a width of the conductive lines in the range of 5-15 μm.

12. The III-nitride light emitting device of claim 11, further comprising an n-type template layer formed on the substrate, wherein the conductive layer is formed on and with ohmic contact to the template layer.

13. The III-nitride light emitting device of claim 11, further comprising a protection layer conformably formed on the conductive grid, wherein the protection layer is made of silicon dioxide, silicon nitride, or titanium dioxide.

14. The III-nitride light emitting device of claim 13, wherein the protection layer comprises one or more pairs of silicon dioxide/titanium dioxide layers forming a distributed Bragg reflector with visible light reflectivity greater than 95%.

15. The III-nitride light emitting device of claim 12, wherein the conductive grid is formed as conductive lines on the template layer, or as conductive lines in trenches in the template layer.

16. The III-nitride light emitting device of claim 11, wherein the conductive grid is formed as conductive lines on the substrate, or as conductive lines in trenches in the substrate.

17. The III-nitride light emitting device of claim 11, wherein the conductive grid is a two-dimensional square grid, or a hexagonal grid, and is uniformly distributed over the substrate.

18. The III-nitride light emitting device of claim 11, wherein the conductive grid is made of Scandium nitride (ScN), Yttrium nitride (YN), Titanium nitride (TiN), Zirconium nitride (ZrN), Hafnium nitride (HfN), Vanadium nitride (VN), Niobium nitride (NbN), Tantalum nitride (TaN), Chromium nitride (CrN), Molybdenum nitride (MoN), or Tungsten nitride (WN).

19. A wafer for III-nitride light emitting device using the wafer substrate of claim 1, comprising:
an n-type layer formed on the wafer substrate;
an active-region formed on the n-type layer; and
a p-type layer formed on the active-region.

20. A Method for fabricating III-nitride light emitting device, comprising
providing a substrate or a template comprising an template layer epitaxially formed on the substrate;
forming a conductive grid made of conductive lines on the substrate or the template, wherein the conductive grid has a separation distance between the conductive lines in the range of 10-150 μm, a thickness of the conductive lines in the range of 0.5-2 μm, and a width of the conductive lines in the range of 5-15 μm;
forming an n-type layer on the substrate or the template and the conductive grid, wherein the n-type layer is in ohmic contact with the conductive grid;
forming an active-region on the n-type layer; and
forming a p-type layer on the active-region.

21. The method for fabricating III-nitride light emitting device of claim 20, further comprising:
etching the p-type layer, the active-region and the n-type layer to expose a portion of the conductive grid to form an LED mesa; and
forming an n-electrode on the exposed conductive grid wherein the n-electrode comprises a contact pad and a finger surrounding the LED mesa.

22. The method for fabricating III-nitride light emitting device of claim 20, wherein the step of forming the conductive grid comprises:
forming a metallic conductive layer on the substrate or the template; and
etching the metallic conductive layer to form the conductive grid.

23. The method for fabricating III-nitride light emitting device of claim 20, wherein the step of forming the conductive grid comprises:
forming a metallic conductive layer on the substrate or the template;
forming a protection layer on the metallic conductive layer; and
etching the protection layer and the metallic conductive layer to form the conductive grid covered with a conformable protection layer resulting from etching the protection layer.

24. The method for fabricating III-nitride light emitting device of claim 20, wherein the step of forming the conductive grid comprises:
forming a metallic conductive layer on the substrate or the template;
forming a visible light distributed Bragg reflector on the metallic conductive layer; and
etching the visible light distributed Bragg reflector and the conductive layer to form the conductive grid covered with a conformable visible light distributed Bragg reflector resulting from etching the visible light distributed Bragg reflector.

25. The method for fabricating III-nitride light emitting device of claim 20, wherein the step of forming the conductive grid comprises:
etching the substrate or the template layer to form trenches therein; and
filling the trenches with a metallic conductive material to form the conductive grid.

26. The method for fabricating III-nitride light emitting device of claim 20, wherein the step of forming the conductive grid comprises:
etching the substrate or the template layer to form trenches therein; and
filling the trenches with a metallic conductive material to form the conductive grid; and
filling the trenches with a protection layer covering the conductive grid.

27. The method for fabricating III-nitride light emitting device of claim 20, wherein the step of forming the conductive grid comprises:
etching the substrate or the template layer to form trenches therein; and
filling the trenches with a metallic conductive material to form the conductive grid; and
filling the trenches with a visible light distributed Bragg reflector covering the conductive grid.

28. The method for fabricating III-nitride light emitting device of claim 20, wherein the conductive grid is made of Scandium nitride (ScN), Yttrium nitride (YN), Titanium nitride (TiN), Zirconium nitride (ZrN), Hafnium nitride (HfN), Vanadium nitride (VN), Niobium nitride (NbN), Tantalum nitride (TaN), Chromium nitride (CrN), Molybdenum nitride (MoN), or Tungsten nitride (WN).

29. The method for fabricating III-nitride light emitting device of claim 23, wherein the protection layer is made of silicon dioxide, silicon nitride, or titanium dioxide.
